(19) United States
(12) Patent Application Publication
(10) Pub. No.: US 2026/0173861 A1
(43) Pub. Date: Jun. 18, 2026

(54) INTEGRATED CAPACITOR FOR SEMICONDUCTOR DEVICE

(71) Applicant: Taiwan Semiconductor Manufacturing Company, Ltd., Hsinchu (TW)

(72) Inventor: Si-Han Tsai, Taichung City (TW)

(21) Appl. No.: 18/983,457

(22) Filed: Dec. 17, 2024

(51) Int. Cl. H01L 23/522; H10D 1/00

(52) U.S. Cl. CPC H10W 20/496; H10D 1/043

(57) ABSTRACT

Some embodiments relate to an integrated device, including: an interconnect structure over a substrate; and a capacitor in the interconnect structure, the capacitor including: a bottom electrode having an upper portion, a first bottom surface, a second bottom surface, and a third bottom surface, an insulative layer, and a top electrode; where the first bottom surface, the second bottom surface, and the third bottom surface are coupled to the upper portion by a first sleeve portion, a second sleeve portion, and a third sleeve portion respectively; where the first sleeve portion is spaced from the second sleeve portion and the third sleeve portion by a first distance measured in a first direction; and where the second sleeve portion is spaced from the third sleeve portion by a second distance measured in a second direction perpendicular to the first direction, the second distance being greater than the first distance.

### BACKGROUND

Integrated circuits (ICs) are used in a wide range of modern-day electronic devices, such as, for example, cameras, cellphones, and the like. Circuit components, such as capacitors, resistors, diodes, and transistors, are formed within the integrated circuits, resulting in circuits of a much smaller scale than those formed of discrete components. As semiconductor manufacturing technology advances, smaller features and components may be made, presenting new challenges to the manufacturing process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, and 1C illustrate a top-down view and cross-sectional views of some embodiments of a capacitor with a dielectric pillar separating capacitor protrusions.

FIGS. 2A, 2B, and 2C illustrate a top-down view and cross-sectional views of some embodiments of a capacitor with a dielectric pillar separating protrusions further comprising a barrier layer.

FIG. 3 illustrates a top-down view of some embodiments of a capacitor with multiple protrusions aligned with multiple parallel lines and separated by dielectric pillars.

FIG. 4 illustrates a top-down view of some embodiments of a capacitor with dielectric pillars in a first line that are closer to the first plane than the second plane.

FIG. 5 illustrates a cross-sectional view of some embodiments of a capacitor with dielectric pillars on a substrate.

FIGS. 6-7, 8A, 8B, and 9-15 illustrate a series of cross-sectional views and a top view of some embodiments of a method of forming a capacitor with a dielectric pillar separating capacitor protrusions.

FIG. 16 illustrates a flowchart of some embodiments of a method of forming a capacitor with a dielectric pillar separating capacitor protrusions.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

Integrated circuits (ICs) comprise a plurality of circuit components, such as capacitors, resistors, transistors, and diodes. The circuit components are formed either on a substrate, within the substrate, or over the substrate within an interconnect structure. The positioning of the circuit components at different parts of the integrated circuit depends in part on the vertical and lateral space used by the circuit component to have desired parameters for the functioning of the circuit.

In some embodiments, capacitors are formed within the interconnect structure. The capacitors are formed within the interconnect structure (as opposed to directly onto the substrate) to take advantage of the greater vertical dimensions available. In some embodiments, capacitors comprise a plurality of protrusions that extend through multiple wire levels, increasing the area and capacitance of the capacitor. Further embodiments also couple a bottom electrode of the capacitor to an underlying wire level, reducing the area of an upper portion of the capacitor that would be used to couple the bottom electrode to the interconnect structure.

As semiconductor technology advances, demand for circuit components of a reduced size increases. To meet this demand, capacitors with a reduced pitch (e.g., a pitch less than 300 nanometers), between parallel protrusions extending from the upper portion are desirable. However, due to the lack of support for the interlayer dielectric during the etching process, the interlayer dielectric surrounding the openings for the protrusions are prone to collapse during the etching process. Therefore, a capacitor with reduced pitch between protrusions and a more stable interlayer dielectric separating the protrusions is desirable.

The present disclosure provides for a capacitor with a plurality of protrusions separated by a plurality of dielectric pillars. The plurality of protrusions comprise a first plurality of protrusions that are separated from one another in a first direction. A second plurality of protrusions is interleaved with the first plurality of protrusions in an alternating pattern in the first direction. A third plurality of protrusions is interleaved with the first plurality of protrusions in an alternating pattern in the first direction, and is separated from the second plurality of protrusions in the second direction by the plurality of dielectric pillars. Dielectric barriers space the first plurality of protrusions from the second and third plurality of protrusions, and extend from outermost sidewalls of the first plurality of protrusions (e.g., sidewalls aligned with the first direction) to the dielectric pillars. The dielectric pillars are spaced from the outermost sidewalls of the first plurality of protrusions (e.g., are at a midpoint of the dielectric barrier, or are closer to the midpoint of the dielectric barrier than the outermost sidewalls), and are configured to support a central portion of the dielectric barrier to prevent the dielectric barrier from collapsing during the initial etching process. By sacrificing a portion of surface area of the capacitor, a capacitor with a reduced pitch (e.g., less than 300 nanometers) between protrusions is fabricated without a collapse of the dielectric barrier.

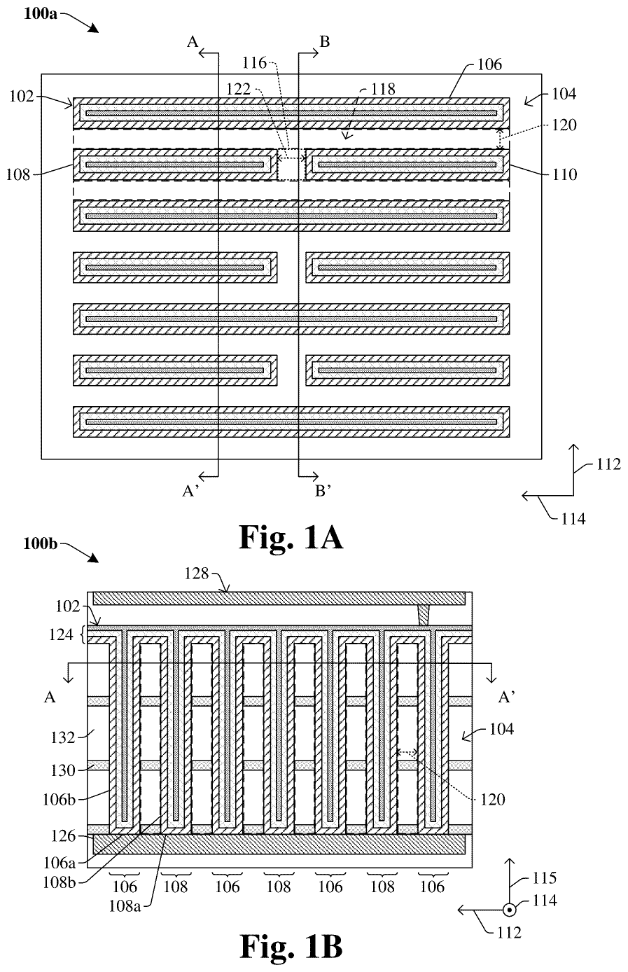

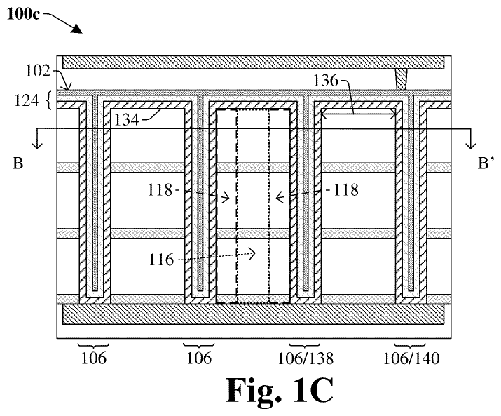

FIGS. 1A, 1B, and 1C illustrate a top-down view 100a and cross-sectional views 100b, 100c of some embodiments of a capacitor with a dielectric pillar separating capacitor protrusions. The cross-sectional view 100b of FIG. 1B is taken along line A-A′ of FIG. 1A. The cross-sectional view 100c of FIG. 1C is taken along the line B-B′ of FIG. 1A.

A capacitor 102 is in an interlayer dielectric 104. The capacitor 102 comprises a first plurality of protrusions 106, a second plurality of protrusions 108, and a third plurality of protrusions 110. The first plurality of protrusions 106 are spaced from one another in a first direction 112. The second plurality of protrusions 108 are interleaved with the first plurality of protrusions 106 in the first direction 112. The third plurality of protrusions 110 are interleaved with the first plurality of protrusions 106 in the first direction 112, and are spaced from the second plurality of protrusions in a second direction 114 perpendicular to the first direction 112.

A plurality of dielectric pillars 116 separate the second plurality of protrusions 108 from the third plurality of protrusions 110. The plurality of dielectric pillars 116 comprise portions of the interlayer dielectric 104 that extend directly between the second plurality of protrusions 108 and the third plurality of protrusions 110. A plurality of dielectric barriers 118 comprise portions of the interlayer dielectric 104 that extend between the first plurality of protrusions 106 and the second and third plurality of protrusions 108, 110 outside of the plurality of dielectric pillars 116. The plurality of dielectric barriers 118 have first thicknesses 120 measured in the first direction 112. The plurality of dielectric pillars 116 have second thicknesses 122 measured in the second direction 114. The second thicknesses 122 are greater than or equal to the first thicknesses 120.

The plurality of dielectric pillars 116 are thicker than the plurality of dielectric barriers 118. Embodiments without the plurality of dielectric pillars experience collapse near the middle of the plurality of dielectric barriers 118 due in part to the lack of a nearby supporting wall and reduced capability of the lithography process to cover dielectric areas with a small pitch and high critical dimension. Therefore, the plurality of dielectric pillars 116 are configured to support the plurality of dielectric barriers 118 by adding an area of increased thickness where the plurality of dielectric barriers 118 are most prone to failure. The increased thickness at a central segment of the plurality of dielectric barriers 118 substantially eliminates the collapse of the plurality of dielectric barriers 118 due to the etching of the interlayer dielectric 104.

As shown in the cross-sectional view 100b of FIG. 1B, the first plurality of protrusions 106 extend from an upper portion 124 of the capacitor 102 to a first wire level 126 of an interconnect structure 128. The second plurality of protrusions 108 extend from the upper portion 124 to the first wire level 126. In some embodiments, the first thickness 120 is between approximately 0.12 and 0.15 micrometers, approximately 0.1 and 0.13 micrometers, approximately 0.1 and 0.15 micrometers, or within another similar range. In some embodiments, the interlayer dielectric 104 comprises a plurality of etch stop layers 130 extending between a plurality of dielectric layers 132.

The first plurality of protrusions 106 comprises first bottom surfaces 106a coupled to the upper portion 124 by first sleeve portions 106b. The second plurality of protrusions 108 comprises second bottom surfaces 108a coupled to the upper portion 124 by second sleeve portions 108b. The third plurality of protrusions 110 comprises third bottom surfaces (not shown) coupled to the upper portion 124 by third sleeve portions (not shown). In some embodiments, the sidewalls of the first sleeve portions 106b, the second sleeve portions 108b, and the third sleeve portions 110b are approximately aligned (e.g., within 10 degrees of being aligned) with a third direction 115 perpendicular to the first direction 112 and the second direction 114.

In some embodiments, the first thickness 120 is measured between the first sleeve portion 106b and the second sleeve portion 108b at the juncture between the sleeve portions and the upper portions 124. In other embodiments, the first thickness 120 is measured between the first sleeve portion 106b and the second sleeve portion 108b at the juncture between the sleeve portions and the first and second bottom surfaces 106a, 108a. In other embodiments, the first thickness 120 is measured between the first sleeve portion 106b and the second sleeve portion 108b at a height between the first bottom surface and the juncture between the first sleeve portion 106b and the upper portion 124.

As shown in the cross-sectional view 100c of FIG. 1C, the plurality of dielectric pillars 116 are confined between dielectric barriers of the plurality of dielectric barriers 118. Further, the plurality of dielectric barriers 118 extend between the plurality of dielectric pillars 116 and the first plurality of protrusions 106. The upper portion 124 of the capacitor 102 has a bottom surface 134. A straight line segment 136 can be drawn across the bottom surface of the upper portion 124 that extends from a first protrusion 138 of the first plurality of protrusions 106 to a second protrusion 140 of the first plurality of protrusions 106.

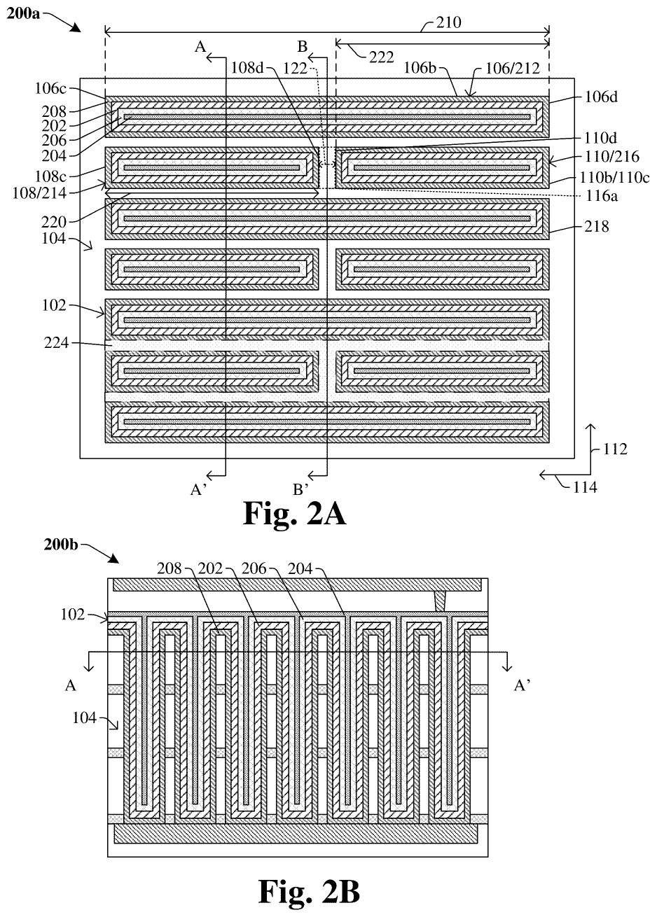

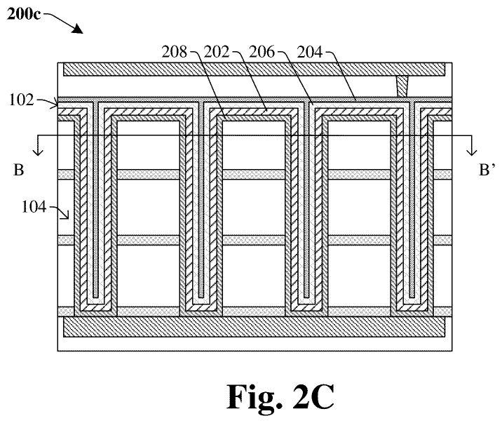

FIGS. 2A, 2B, and 2C illustrate a top-down view 200a and cross-sectional views 200b, 200c of some embodiments of a capacitor with a dielectric pillar separating protrusions further comprising a barrier layer. The cross-sectional view 200b of FIG. 2B is taken along line A-A′ of FIG. 2A. The cross-sectional view 200c of FIG. 2C is taken along the line B-B′ of FIG. 2A. FIGS. 2A, 2B, and 2C are described concurrently.

The capacitor 102 comprises a bottom electrode 202, a top electrode 204, and a insulative layer 206 separating the bottom electrode 202 and the top electrode 204. In some embodiments, a metal barrier layer 208 separates the bottom electrode 202 from the interlayer dielectric 104. The top electrode 204 conforms to upper surfaces and inner sidewalls of the insulative layer 206. The insulative layer 206 conforms to upper surfaces and inner sidewalls of the bottom electrode 202. In some embodiments, the bottom electrode 202 conforms to upper surfaces and inner sidewalls of the metal barrier layer 208. In some embodiments, the metal barrier layer 208 is configured to space the bottom electrode 202 from the interlayer dielectric 104 to prevent material from the bottom electrode 202 from diffusing into the interlayer dielectric. In some embodiments, the second thickness 122 is between approximately 0.17 and 0.2 micrometers, approximately 0.15 and 0.18 micrometers, approximately 0.15 and 0.2 micrometers, or within another similar range.

The first sleeve portions 106b of the first plurality of protrusions 106 extend a first distance 210 between first outermost sidewalls 106c and second outermost sidewalls 106d. The first distance 210 is substantially equal to the distance between first outermost sidewalls 108c of the second sleeve portions 108b and first outermost sidewalls 110c of third sleeve portions 110b. That is, in some embodiments, the first outermost sidewalls 108c of the second plurality of protrusions 108 are substantially aligned with the first outermost sidewalls 106c of the first plurality of protrusions 106, and the first outermost sidewalls 110c of the third plurality of protrusions 110 are substantially aligned with the second outermost sidewalls 106d of the first plurality of protrusions 106. In some embodiments, the first distance 210 is approximately between 1.4 micrometers and 1.55 micrometers, approximately between 1.45 and 1.6 micrometers, approximately between 1.4 and 1.6 micrometers, or within another similar range.

Second outermost sidewalls 108d of the second plurality of protrusions 108 are opposite the first outermost sidewalls 108c and face the third plurality of protrusions 110. The second outermost sidewalls 108d are a second distance 220 from the first outermost sidewalls 108c. Second outermost sidewalls 110d of the third plurality of protrusions 110 are opposite the first outermost sidewalls 110c and face the second plurality of protrusions 108. The second outermost sidewalls 110d are a third distance 222 from the first outermost sidewalls 110c, where the third distance 222 is substantially equal to (e.g., within 5% of) the second distance 220.

The first protrusion 212, the second protrusion 214, the third protrusion 216, and the fourth protrusion 218 have substantially rectangular cross-sections from a top down perspective. In some embodiments, the first protrusion 212, the second protrusion 214, the third protrusion 216, and the fourth protrusion 218 having a length extending in the second direction 114 greater than a width extending in the first direction 112. The second plurality of protrusions 108 have sidewalls that are substantially aligned with sidewalls of the and the third plurality of protrusions 110 that extend in the second direction 114. The substantially aligned sidewalls of the second plurality of protrusions 108 and the third plurality of protrusions 110 extend in the second direction the second distance 220 that is less than the first distance 210.

The first plurality of protrusions 106 has a first protrusion 212, the second plurality of protrusions 108 has a second protrusion 214, and the third plurality of protrusions 110 has a third protrusion 216. The first plurality of protrusions 106 has a fourth protrusion 218 spaced from the first protrusion 212 by the second protrusion 214 and the third protrusion 216. The second protrusion 214, the third protrusion 216, and a dielectric pillar 116a separating the second protrusion 214 and the third protrusion 216 are confined between outer sidewalls of the first protrusion 212 and the fourth protrusion 218 in the first direction 112. In some embodiments, contiguous portions of the interlayer dielectric 104 extending directly between protrusions of the first plurality of protrusions 106, the second plurality of protrusions 108, and the third plurality of protrusions 110 form one or more “H” shapes 224 from a top down perspective.

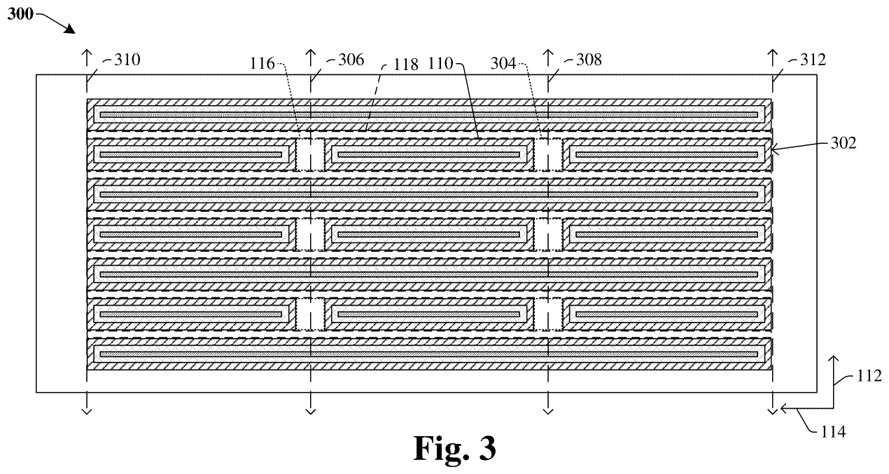

FIG. 3 illustrates a top-down view 300 of some embodiments of a capacitor with multiple protrusions aligned with multiple parallel lines and separated by dielectric pillars.

In some embodiments, a fourth plurality of protrusions 302 is spaced from the third plurality of protrusions 110 by a second plurality of dielectric pillars 304. The second plurality of dielectric pillars 304 are configured to stabilize the plurality of dielectric barriers 118 in conjunction with the plurality of dielectric pillars 116. In embodiments where a first line of dielectric pillars (e.g., the plurality of dielectric pillars 116) would not eliminate or mitigate the collapse of the plurality of dielectric barriers 118 (e.g., due to the dielectric barriers having a length (see the first distance 210) between approximately 1.6 and 2.1 micrometers, between approximately 2 and 2.4 micrometers, within another similar range, or due to a different reason), a second line of dielectric pillars (e.g., the second plurality of dielectric pillars 304) is introduced.

In some embodiments, the plurality of dielectric pillars 116 are arranged in a first straight line 306 extending in the first direction 112, and the second plurality of dielectric pillars 304 are arranged in a second straight line 308 extending in the first direction 112. In some embodiments, the first straight line 306 is equally spaced from the second straight line 308 and a first plane 310 extending along first outer sidewalls of the first plurality of protrusions 106 in the first direction 112. In some embodiments, the second straight line 308 is equally spaced from the first straight line 306 and a second plane 312 extending along second outer sidewalls of the first plurality of protrusions in the first direction 112. It will be appreciated that some embodiments have additional lines of dielectric pillars spaced between the first plane 310 and the second plane 312.

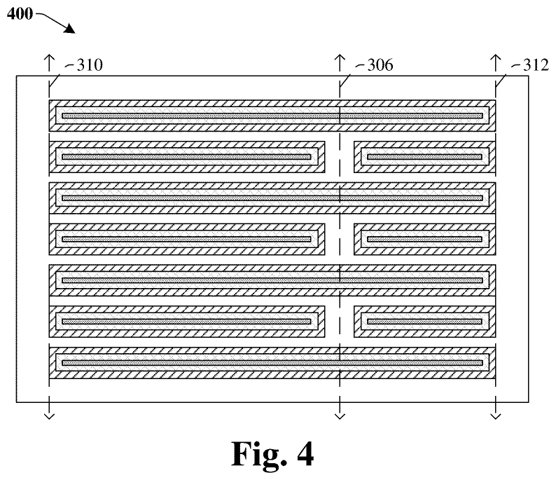

FIG. 4 illustrates a top-down view 400 of some embodiments of a capacitor with dielectric pillars in a first line that are closer to the first plane than the second plane. In some embodiments, the plurality of dielectric pillars 116 in the first straight line 306 are not evenly spaced from the first plane 310 and the second plane 312. That is, the first straight line 306 is closer to one of the first plane 310 or the second plane 312 than the other of the first plane 310 or the second plane 312. In embodiments where the plurality of dielectric barriers 118 are prone to failure in a specific region due to positioning or variation in the manufacturing process across a wafer (e.g., variations in the lithography or etching process), altering the positioning of the plurality of dielectric pillars 116 closer to the specific region of the plurality of dielectric barriers 118 further mitigates fabrication errors during the manufacturing of the capacitor.

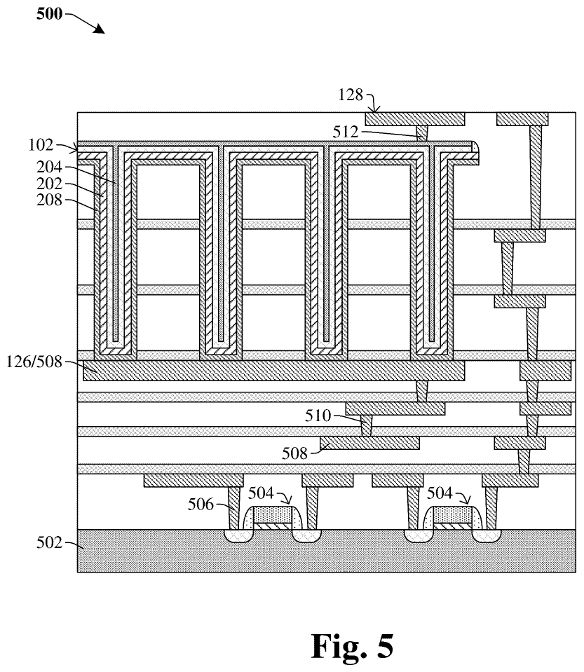

FIG. 5 illustrates a cross-sectional view 500 of some embodiments of a capacitor with dielectric pillars on a substrate.

In some embodiments, the capacitor 102 overlies a substrate 502. A plurality of semiconductor devices 504 are on or over the substrate. In some embodiments, the plurality of semiconductor devices 504 are or comprise a transistor device (e.g., a planar FET, a FinFET, a gate-all-around (GAA) device, etc.). The plurality of semiconductor devices 504 are coupled to the interconnect structure 128 using a plurality of contacts 506. The interconnect structure 128 has a plurality of wire levels 508 (comprising the first wire level 126) and a plurality of via levels 510. In some embodiments, the capacitor 102 extends through one or more of the plurality of wire levels 508 and the plurality of via levels 510. The top electrode 204 is coupled to the plurality of wire levels 508 by a first via 512. In some embodiments, the bottom electrode 202 is coupled to the plurality of wire levels through direct contact with the first wire level 126 or the metal barrier layer 208 contacting the first wire level 126. In other embodiments, the bottom electrode 202 is coupled to the interconnect structure 128 through a second via (not shown).

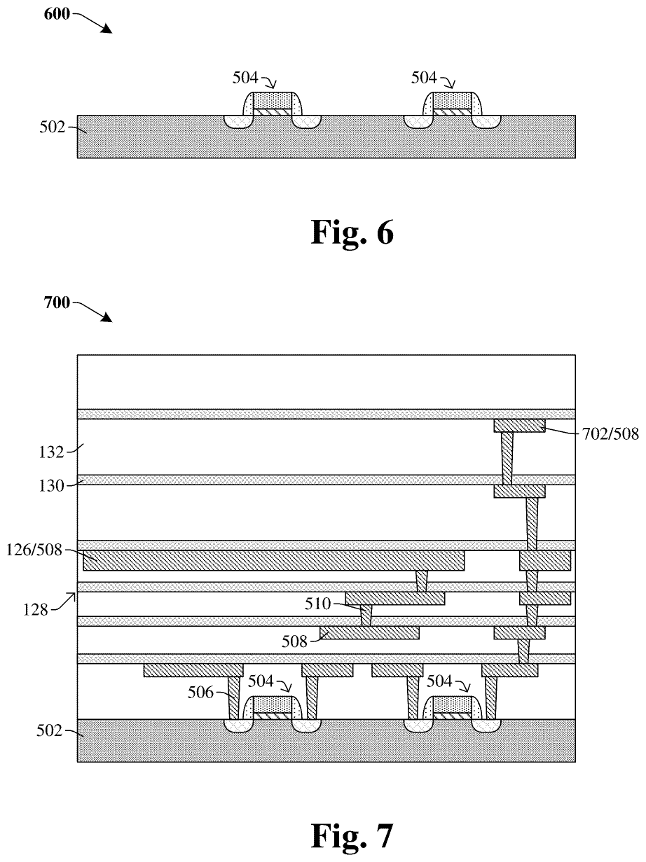

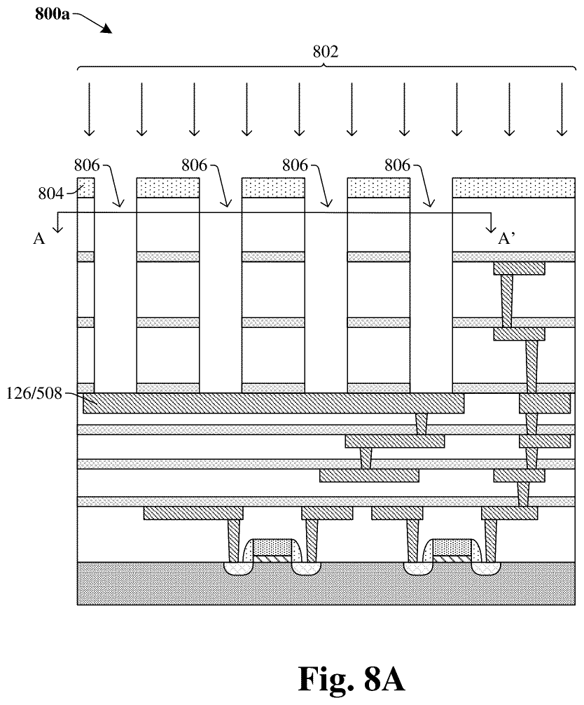

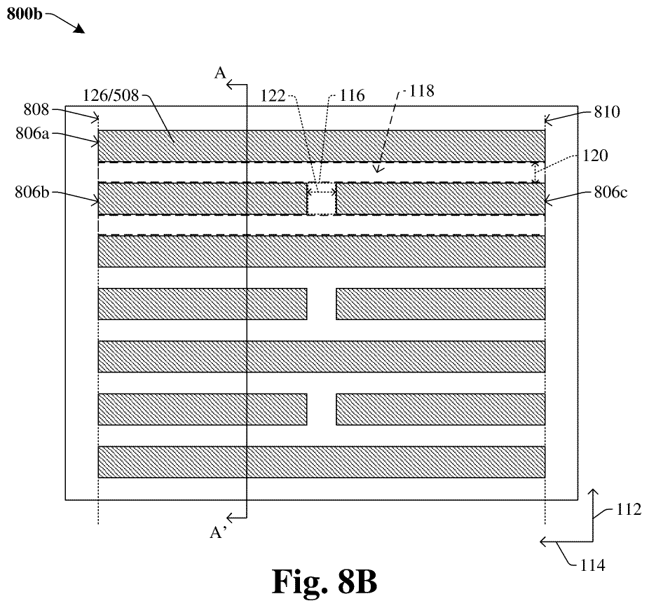

FIGS. 6-7, 8A, 8B, and 9-15 illustrate a series of cross-sectional views 600-700, 800a, 900-1500 and a top down view 800b of some embodiments of a method of forming a capacitor with a dielectric pillar separating capacitor protrusions. Although FIGS. 6-7, 8A, 8B, and 9-14 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. The cross-sectional view 800a of FIG. 8A is taken along line A-A′ of FIG. 8B.

As shown in the cross-sectional view 600 of FIG. 6, the plurality of semiconductor devices 504 are formed on a substrate 502. In some embodiments, the plurality of semiconductor devices 504 are or comprise a transistor device (e.g., a planar FET, a FinFET, a gate-all-around (GAA) device, etc.). The plurality of semiconductor devices 504 comprises a pair of source/drain regions, semiconductor channels, gate dielectrics, and gate terminals. In some embodiments, the source/drain regions are formed using an implantation process. In some embodiments, the gate dielectrics and gate terminals are formed using a plurality of etching processes, a plurality of deposition processes, or the like.

As shown in the cross-sectional view 700 of FIG. 7, a first portion of an interconnect structure 128 is formed within an interlayer dielectric 104. The first portion of the interconnect structure 128 comprises a plurality of wire levels 508, comprising a first wire level 126 and a first upper wire level 702 that is the uppermost wire level in the first portion of the interconnect structure 128. The first portion of the interconnect structure 128 further comprises a plurality of via levels 510 extending between the plurality of wire levels 508. A plurality of contacts 506 extend between the plurality of semiconductor devices and the interconnect structure 128. In some embodiments, the interconnect structure 128 comprises a conductive material, such as copper, aluminum, tungsten, a conductive metal alloy, or the like.

The interlayer dielectric 104 comprises a plurality of etch stop layers 130 and a plurality of dielectric layers 132. In some embodiments, the plurality of dielectric layers 132 are or comprise an insulative material, such as silicon dioxide (SiO₂), or the like. In some embodiments, the plurality of etch stop layers 130 are or comprise an insulative material different from the material of the plurality of dielectric layers 132, such as silicon nitride (Si₃N₄), or the like. In some embodiments, the interlayer dielectric 104 is formed using one or more of physical vapor deposition (PVD), atomic layer deposition (ALD), chemical vapor deposition (CVD), or the like. In some embodiments, the interconnect structure 128 is formed using one or more of PVD, ALD, CVD, a damascene process, a dual damascene process, or the like.

As shown in the cross-sectional view 800a of FIG. 8A, a first masking layer 804 is formed on the interlayer dielectric 104. In some embodiments, the first masking layer 804 is or comprises a photoresist. In some embodiments the first masking layer 804 is formed on the interlayer dielectric 104 using one or more of PVD, ALD, CVD, a spin on process, or the like. Subsequently, the first masking layer 804 is patterned. In some embodiments, the first masking layer 804 is patterned using photolithography to expose portions of the interlayer dielectric 104 corresponding to the first, second, and third plurality of protrusions (see 106, 108, 110 of FIG. 1A).

After the forming and patterning of the first masking layer 804, a first etching process 802 is performed on the interlayer dielectric 104. The first etching process 802 results in a plurality of openings 806 extending into the interlayer dielectric 104, exposing the first wire level 126. In some embodiments, the first etching process 802 is an anisotropic dry etching process. After the first etching process 802, the first masking layer 804 is removed from the interlayer dielectric. In some embodiments, the plurality of openings 806 extend beneath the first upper wire level 702.

As shown in the top down view 800b of FIG. 8B, after the plurality of openings 806 are formed, the plurality of dielectric pillars 116 and the plurality of dielectric barriers 118 remain over the first wire level 126. The second thickness 122 of the plurality of dielectric pillars 116 being greater than or equal to the first thickness 120 of the plurality of dielectric barriers 118 in addition to the mechanical coupling of the plurality of dielectric pillars 116 to a central portion of the plurality of dielectric barriers 118 stabilizes the plurality of dielectric barriers 118. This stabilization eliminates or substantially eliminates the collapse of the plurality of dielectric barriers 118 during the first etching process (see 802 of FIG. 8A).

The plurality of openings 806 comprise a first plurality of openings 806a extending from a first vertical plane 808 perpendicular to the second direction 114 to a second vertical plane 810 perpendicular to the second direction 114. The plurality of openings 806 further comprise a second plurality of openings 806b extending a second distance 220 from a first vertical plane 808 to a dielectric pillar of the plurality of dielectric pillars 116. The plurality of openings 806 further comprise a third plurality of openings 806c extending a third distance 222 from the second vertical plane 810 to a dielectric pillar of the plurality of dielectric pillars 116. After the plurality of openings 806 are formed, the plurality of dielectric barriers 118 remain on the substrate (see 502 of FIG. 5). The plurality of dielectric barriers 118 extend from the first vertical plane 808 to the second vertical plane 810 and are substantially parallel to one another and the second direction 114.

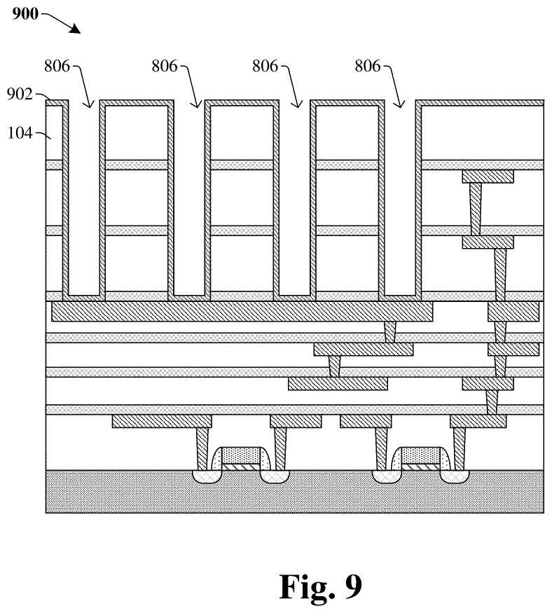

As shown in the cross-sectional view 900 of FIG. 9, a conformal barrier layer 902 is deposited over the interlayer dielectric 104 and into the plurality of openings 806. In some embodiments, the conformal barrier layer 902 is or comprises a conductive metal layer that diffuses into silicon at a lower rate than copper, such as nickel (Ni), aluminum (Al), tantalum (Ta), tantalum nitride (TaN), ruthenium (Ru), tungsten (W), or the like. In some embodiments, the conformal barrier layer 902 is deposited using one or more of PVD, ALD, CVD, or the like.

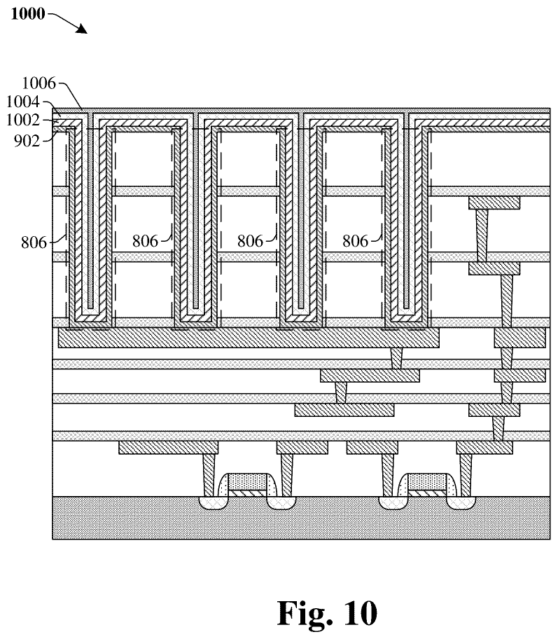

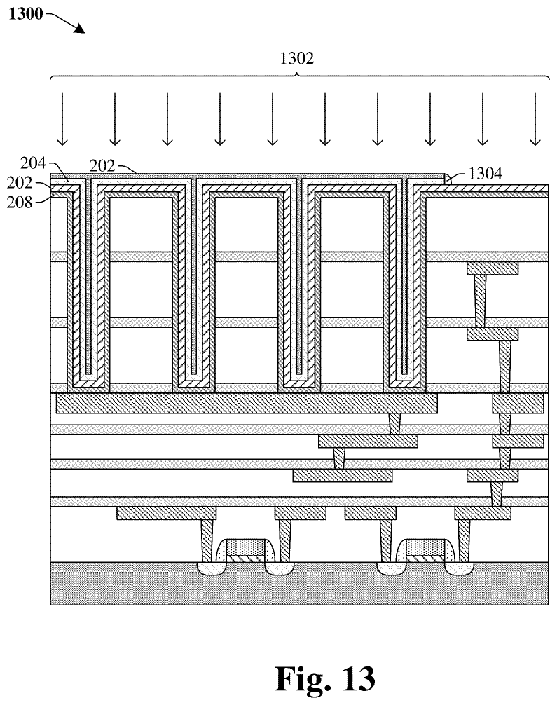

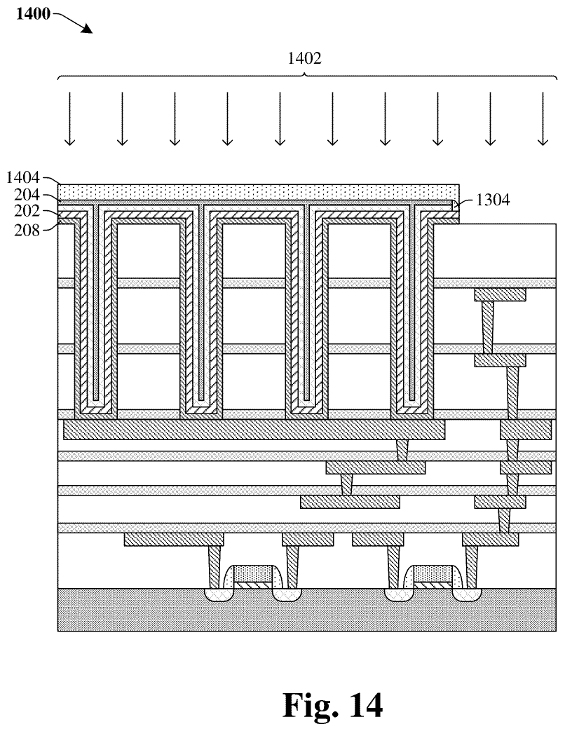

As shown in the cross-sectional view 1000 of FIG. 10, a conformal bottom electrode layer 1002, a conformal insulative layer 1004, and a conformal top electrode layer 1006 are formed over the interlayer dielectric, filling the plurality of openings 806 (shown in phantom). In some embodiments, the conformal bottom electrode layer 1002 and the conformal top electrode layer 1006 is or comprises a conductive material such as copper (Cu), gold (Au), nickel (Ni), aluminum (Al), tantalum (Ta), tantalum nitride (TaN), ruthenium (Ru), tungsten (W), or the like. In some embodiments, the conformal insulative layer 1004 is or comprises a high-k dielectric material, such as hafnium dioxide (HfO₂), zirconium dioxide (ZrO₂) or the like. In some embodiments, the conformal bottom electrode layer 1002, the conformal insulative layer 1004, and the conformal top electrode layer 1006 are formed using a plurality of deposition processes (e.g., PVD, ALD, CVD), or the like. In further embodiments, a seed layer is formed on the underlying material before the formation of the conformal bottom electrode layer 1002 and the conformal top electrode layer 1006 to improve the deposition of the conductive material. In some embodiments, an additional etch stop layer (not shown) is formed over the conformal top electrode layer 1006 to help pattern the conformal bottom electrode layer 1002 and the conformal barrier layer 902 (see FIG. 13).

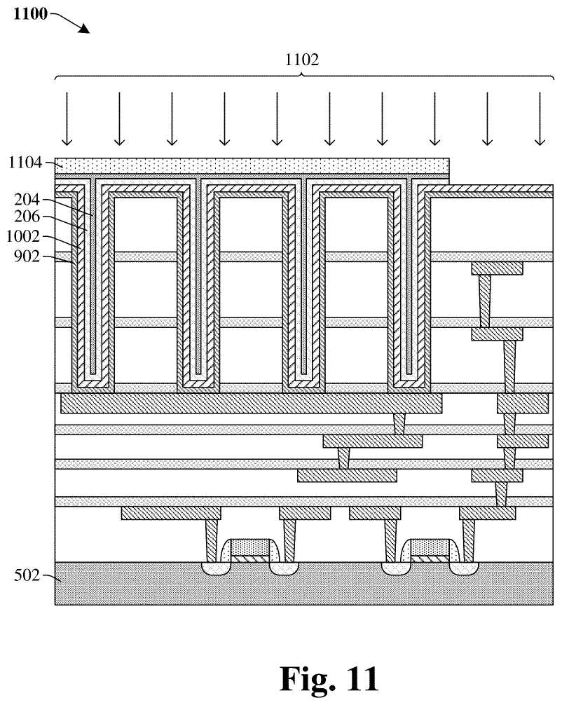

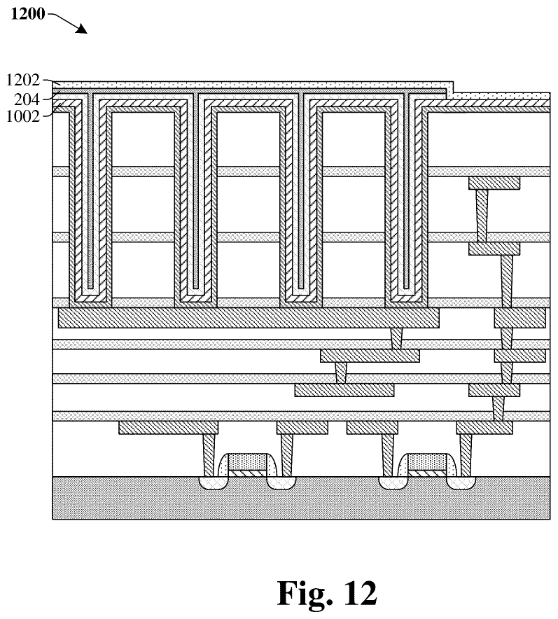

As shown in the cross-sectional view 1100 of FIG. 11, a second masking layer 1104 is formed over the conformal top electrode layer (see 1006 of FIG. 10). In some embodiments, the second masking layer 1104 is or comprises a photoresist and is patterned using photolithography. The pattern of the second masking layer 1104 corresponds to the position of the top electrode 204.

After the second masking layer 1104 is formed, a second etching process 1102 is performed, removing portions of the conformal top electrode layer (see 1006 of FIG. 10) and the conformal insulative layer (see 1004 of FIG. 10), causing the top electrode 204 and the insulative layer 206 to remain on conformal bottom electrode layer 1002 and the conformal barrier layer 902. In embodiments where the additional etch stop layer (not shown) is formed over the conformal top electrode layer (see 1006 of FIG. 10), the additional etch stop layer is also etched by the second etching process 1102. The second masking layer 1104 is subsequently removed.

As shown in the cross-sectional view 1200 of FIG. 12, a conformal dielectric layer 1202 is formed on the top electrode 204 and the conformal bottom electrode layer 1002. In some embodiments, the conformal dielectric layer 1202 is or comprises an insulative material, such as silicon oxide (SiO₂), silicon nitride (Si₃N₄), or the like. In some embodiments, the conformal dielectric layer 1202 is formed sing one or more deposition processes, such as PVD, ALD, CVD, or the like. In embodiments with the additional etch stop layer, the conformal dielectric layer 1202 conforms to the upper surface and sidewalls of the additional etch stop layer.

As shown in the cross-sectional view 1300 of FIG. 13, a third etching process 1302 (e.g., a dry etching process) is performed. The third etching process 1302 results in portions of the conformal dielectric layer (see 1202 of FIG. 12) being removed from an upper surface of the top electrode 204, resulting in the remaining dielectric 1304 being directly above an upper surface of the conformal bottom electrode layer 1002. The remaining dielectric 1304 shields outer sidewalls of the top electrode 204 and the insulative layer 206 from conductive residue resulting from subsequent etching processes.

As shown in the cross-sectional view 1400 of FIG. 14, a third masking layer 1404 is formed on the top electrode 204 and the remaining dielectric 1304. In some embodiments, the third masking layer 1404 is or comprises a photoresist. In some embodiments the third masking layer 1404 is formed on the top electrode 204 using one or more of PVD, ALD, CVD, a spin on process, or the like. Subsequently, the third masking layer 1404 is patterned. In some embodiments, the third masking layer 1404 is patterned using photolithography to cover portions of the conformal bottom electrode layer (see 1002 of FIG. 10) corresponding to the bottom electrode 202 and expose portions of the conformal bottom electrode layer (see 1002 of FIG. 10) beyond the bottom electrode 202.

After the forming and patterning of the third masking layer 1404, a fourth etching process 1402 is performed on the interlayer dielectric 104. The fourth etching process 1402 results in the patterning of the conformal bottom electrode layer (see 1002 of FIG. 10) and the conformal barrier layer (see 902 of FIG. 9) into the bottom electrode 202 and the metal barrier layer 208, respectively. In some embodiments, the fourth etching process 1402 is an anisotropic dry etching process. After the fourth etching process 1402, the third masking layer 1404 is removed.

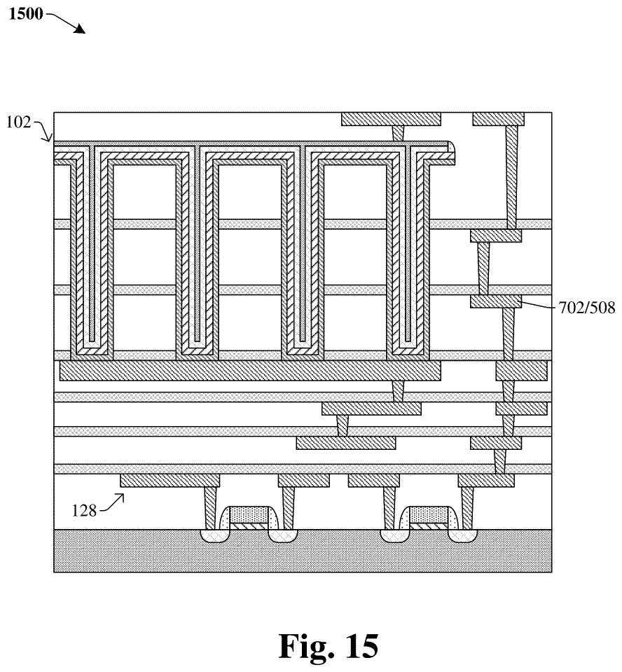

As shown in the cross-sectional view 1500 of FIG. 15, a second portion of the interconnect structure 128 is formed over the capacitor 102. In some embodiments, the second portion of the interconnect structure 128 is electrically coupled to the first portion of the interconnect structure through the first upper wire level 702. In some embodiments, the second portion of the interconnect structure is or comprises the same materials as the first portion of the interconnect structure 128 and is formed using the same methods as the first portion of the interconnect structure 128.

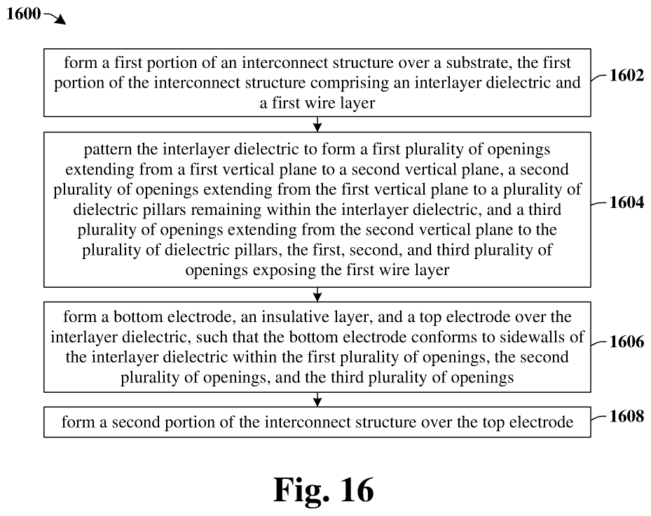

FIG. 16 illustrates a flowchart 1600 of some embodiments of a method of forming a capacitor with a dielectric pillar separating capacitor protrusions. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 1602, a first portion of an interconnect structure is formed over a substrate, the first portion of the interconnect structure comprising an interlayer dielectric and a first wire layer. An example of a drawing illustrating this step can be found, for example, in FIG. 6.

At 1604, the interlayer dielectric is patterned to form a first plurality of openings extending from a first vertical plane to a second vertical plane, a second plurality of openings extending from the first vertical plane to a plurality of dielectric pillars remaining within the interlayer dielectric, and a third plurality of openings extending from the second vertical plane to the plurality of dielectric pillars, the first, second, and third plurality of openings exposing the first wire layer. An example of a drawing illustrating this step can be found, for example, in FIGS. 8A-8B.

At 1606, a bottom electrode, an insulative layer, and a top electrode are formed over the interlayer dielectric, such that the bottom electrode conforms to sidewalls of the interlayer dielectric within the first plurality of openings, the second plurality of openings, and the third plurality of openings. An example of a drawing illustrating this step can be found, for example, in FIGS. 9-14.

At 1608, a second portion of the interconnect structure is formed over the top electrode. An example of a drawing illustrating this step can be found, for example, in FIG. 14.

Some embodiments relate to an integrated device, including: an interconnect structure over a substrate; and a capacitor in the interconnect structure, the capacitor including: a bottom electrode having an upper portion, a first bottom surface, a second bottom surface, and a third bottom surface, a top electrode overlying the bottom electrode, and an insulative layer separating the bottom electrode from the top electrode; where the first bottom surface, the second bottom surface, and the third bottom surface are coupled to the upper portion by a first sleeve portion, a second sleeve portion, and a third sleeve portion respectively; where the first sleeve portion is spaced from the second sleeve portion and the third sleeve portion by a first distance measured in a first direction; and where the second sleeve portion is spaced from the third sleeve portion by a second distance measured in a second direction perpendicular to the first direction, the second distance being greater than the first distance.

Other embodiments relate to an integrated device, including: an interconnect structure overlying a substrate; and a capacitor within the interconnect structure, the capacitor including: a first upper portion; a first plurality of protrusions extending from the first upper portion, spaced from each other in a first direction, and extending a first distance in a second direction between first outer sidewalls and second outer sidewalls of the first plurality of protrusions; a second plurality of protrusions extending from the first upper portion, having first outermost sidewalls substantially aligned with the first outer sidewalls of the first plurality of protrusions, and extending in the second direction a second distance that is less than the first distance; and a third plurality of protrusions extending from the first upper portion, having first outermost sidewalls substantially aligned with the second outer sidewalls of the first plurality of protrusions, and extending in the second direction towards the second plurality of protrusions a third distance, the third distance being substantially equal to the second distance.

Yet other embodiments relate to a method of forming an integrated device, including: forming a first portion of an interconnect structure over a substrate, the first portion of the interconnect structure comprising an interlayer dielectric and a first wire layer; patterning the interlayer dielectric to form a first plurality of openings extending from a first vertical plane to a second vertical plane, a second plurality of openings extending from the first vertical plane to a plurality of dielectric pillars remaining within the interlayer dielectric, and a third plurality of openings extending from the second vertical plane to the plurality of dielectric pillars, the first, second, and third plurality of openings exposing the first wire layer; and forming a bottom electrode, an insulative layer, and a top electrode over the interlayer dielectric, such that the bottom electrode conforms to sidewalls of the interlayer dielectric within the first plurality of openings, the second plurality of openings, and the third plurality of openings.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
an interconnect structure over a substrate; and
a capacitor in the interconnect structure, the capacitor comprising: a bottom electrode having an upper portion, a first bottom surface, a second bottom surface, and a third bottom surface, a top electrode overlying the bottom electrode, and an insulative layer separating the bottom electrode from the top electrode;
wherein the first bottom surface, the second bottom surface, and the third bottom surface are coupled to the upper portion by a first sleeve portion, a second sleeve portion, and a third sleeve portion respectively;
wherein the first sleeve portion is spaced from the second sleeve portion and the third sleeve portion by a first distance measured in a first direction; and
wherein the second sleeve portion is spaced from the third sleeve portion by a second distance measured in a second direction perpendicular to the first direction, the second distance being greater than the first distance.

2. The integrated device of claim 1, wherein the first sleeve portion has a first width measured in the second direction, and wherein an outermost sidewall of the second sleeve portion is a third distance from an outermost sidewall of the third sleeve portion, the third distance being substantially equal to the first width.

3. The integrated device of claim 1, wherein the capacitor further comprises a fourth bottom surface and a fourth sleeve portion coupling the fourth bottom surface to the upper portion, wherein the fourth sleeve portion is spaced from the first sleeve portion in the first direction by the second sleeve portion and the third sleeve portion.

4. The integrated device of claim 3, wherein the second sleeve portion and the third sleeve portion are confined between outer sidewalls of the first sleeve portion and the fourth sleeve portion.

5. The integrated device of claim 1, wherein the first sleeve portion has a substantially rectangular cross-section when viewed from a top down view, the substantially rectangular cross-section having a length extending in the second direction greater than a width extending in the first direction;
wherein a first outer sidewall of the first sleeve portion is substantially parallel to the second direction;
wherein the second sleeve portion and the third sleeve portion have second substantially rectangular cross-sections when viewed from a top-down view, the second substantially rectangular cross-sections having a length extending in the second direction greater than a width extending in the first direction; and
wherein a second outer sidewall of the second sleeve portion is substantially aligned with a third outer sidewall of the third sleeve portion, and the second outer sidewall and the third outer sidewall extending primarily in the second direction.

6. The integrated device of claim 5, wherein the second outer sidewall of the second sleeve portion and the third outer sidewall of the third sleeve portion faces the first outer sidewall of the first sleeve portion.

7. An integrated device, comprising:
an interconnect structure overlying a substrate; and
a capacitor within the interconnect structure, the capacitor comprising:
a first upper portion;
a first plurality of protrusions extending from the first upper portion, spaced from each other in a first direction, and extending a first distance in a second direction between first outer sidewalls and second outer sidewalls of the first plurality of protrusions;
a second plurality of protrusions extending from the first upper portion, having first outermost sidewalls substantially aligned with the first outer sidewalls of the first plurality of protrusions, and extending in the second direction a second distance that is less than the first distance; and
a third plurality of protrusions extending from the first upper portion, having first outermost sidewalls substantially aligned with the second outer sidewalls of the first plurality of protrusions, and extending in the second direction towards the second plurality of protrusions a third distance, the third distance being substantially equal to the second distance.

8. The integrated device of claim 7, wherein the second plurality of protrusions further comprises second outermost sidewalls opposite the first outermost sidewalls of the second plurality of protrusions, the second outermost sidewalls the second distance from the first outermost sidewalls of the second plurality of protrusions and facing the third plurality of protrusions; and
wherein the third plurality of protrusions further comprises second outermost sidewalls opposite the first outermost sidewalls of the third plurality of protrusions, the second outermost sidewalls the third distance from the first outermost sidewalls of the third plurality of protrusions and facing the second plurality of protrusions.

9. The integrated device of claim 7, wherein the first plurality of protrusions, the second plurality of protrusions, and the third plurality of protrusions extend to a first metal layer, and are separated by an interlayer dielectric.

10. The integrated device of claim 9, further comprising a plurality of dielectric pillars within the interlayer dielectric, the plurality of dielectric pillars spacing the second plurality of protrusions from the third plurality of protrusions and having thicknesses measured in the second direction; and
a plurality of dielectric barriers within the interlayer dielectric spacing protrusions of the first plurality of protrusions from protrusions of the second plurality of protrusions in the first direction, wherein the plurality of dielectric barriers have thicknesses measured in the first direction that are less than the thicknesses of the plurality of dielectric pillars measured in the second direction.

11. The integrated device of claim 7, wherein the first plurality of protrusions comprises a first protrusion and a second protrusion, and wherein a straight line segment can extend from the first protrusion to the second protrusion without contacting the second plurality of protrusions or the third plurality of protrusions.

12. The integrated device of claim 7, further comprising an interlayer dielectric extending between outer sidewalls of the first plurality of protrusions, the second plurality of protrusions, and the third plurality of protrusions, and wherein contiguous portions of the interlayer dielectric extending directly between protrusions of the first plurality of protrusions, the second plurality of protrusions, and the third plurality of protrusions form one or more “H” shapes from a top down perspective.

13. A method of forming an integrated device, comprising:
forming a first portion of an interconnect structure over a substrate, the first portion of the interconnect structure comprising an interlayer dielectric and a first wire layer;
patterning the interlayer dielectric to form a first plurality of openings extending from a first vertical plane to a second vertical plane, a second plurality of openings extending from the first vertical plane to a plurality of dielectric pillars remaining within the interlayer dielectric, and a third plurality of openings extending from the second vertical plane to the plurality of dielectric pillars, the first, second, and third plurality of openings exposing the first wire layer; and
forming a bottom electrode, an insulative layer, and a top electrode over the interlayer dielectric, such that the bottom electrode conforms to sidewalls of the interlayer dielectric within the first plurality of openings, the second plurality of openings, and the third plurality of openings.

14. The method of claim 13, wherein the first plurality of openings are spaced from the second plurality of openings and the third plurality of openings by first thicknesses measured in a first direction, and the plurality of dielectric pillars have second thicknesses measured in a second direction perpendicular to the first direction, wherein the second thicknesses are greater than the first thicknesses.

15. The method of claim 13, wherein the bottom electrode comprises a plurality of bottom surfaces in the first, second, and third plurality of openings, wherein the plurality of bottom surfaces are electrically coupled to the first wire layer.

16. The method of claim 15, wherein forming the bottom electrode, the insulative layer, and the top electrode further comprises:
forming a conformal bottom electrode layer over the interlayer dielectric, the conformal bottom electrode layer conforming to inner sidewalls of the interlayer dielectric;
depositing a conformal insulative layer over the conformal bottom electrode layer, the conformal insulative layer conforming to inner sidewalls of the conformal bottom electrode layer; and
forming a conformal top electrode layer over the conformal insulative layer, filling the first, second, and third plurality of openings and conforming to inner sidewalls of the conformal insulative layer.

17. The method of claim 13, wherein the first vertical plane is parallel to the second vertical plane.

18. The method of claim 13, wherein the first plurality of openings, the second plurality of openings, and the third plurality of openings are patterned concurrently.

19. The method of claim 13, wherein after patterning the interlayer dielectric, dielectric barrier portions of the interlayer dielectric extend from the first vertical plane and the second vertical plane to the plurality of dielectric pillars.

20. The method of claim 19, wherein the dielectric barrier portions of the interlayer dielectric are substantially parallel to one another.
